(19) United States
(12) Patent Application Publication
(10) Pub. No.: US 2021/0192313 A1
(43) Pub. Date: Jun. 24, 2021

(54) ELECTRONIC SYNAPTIC DEVICE BASED ON NANOCOMPOSITES INCLUDING PROTEIN AND METHOD OF MANUFACTURING THE SAME

(71) Applicant: IUCF-HYU (INDUSTRY-UNIVERSITY COOPERATION FOUNDATION HANYANG UNIVERSITY), Seoul (KR)

(72) Inventors: Tae Whan KIM, Seoul (KR); Sihyun SUNG, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 16/952,989

(22) Filed: Nov. 19, 2020

(30) Foreign Application Priority Data
Dec. 19, 2019 (KR) 10-2019-0170711

(51) Int. Cl. G06N 3/00; H01L 51/05; H01L 51/00

(52) U.S. Cl. CPC G06N 3/002; H01L 51/0003; H01L 51/0093; H01L 51/0595

(57) ABSTRACT

The present invention relates to an electronic synaptic device and a method of manufacturing the same, and more specifically, to a human-friendly electronic synaptic device based on nanocomposites including a protein, and a method of manufacturing the same.

### CLAIM FOR PRIORITY

This application claims priority to Korean Patent Application No. 2019-0170711 filed on Dec. 19, 2019 in the Korean Intellectual Property Office (KIPO), the entire contents of which are hereby incorporated by reference.

### BACKGROUND

### 1. Technical Field

The present invention relates to an electronic synaptic device and a method of manufacturing the same, and more specifically, to a human-friendly electronic synaptic device based on nanocomposites including a protein, and a method of manufacturing the same.

### 2. Related Art

Currently, due to huge amounts of power and time consumption between memory units and central processing devices, the conventional digital computer architectures based on alternative complementary metal-oxide semiconductor (CMOS) silicon technology are facing the Von Neumann bottleneck in order to process data. In such situations, due to advantages in terms of a high-speed process and improved energy efficiency, biomimetic brain-based hardware platforms are emerging as one of the best ways to implement neuromorphic systems with low power and large capacity.

Recent interest in the biomimetic brain has led to the development of a single component with synaptic properties. The human brain uses enormous numbers of synapses and neurons to perform learning and memory functions. The brain can process a tremendous amount of information at once but consumes very little energy. In addition, synapses play an important role in forming a process memory through adaptability and fault tolerant operation because a parallel connection level thereof is high. For this reason, the development of an artificial synaptic device, which functions in a manner similar to a biological synapse, has become an important element of research on neuromorphic systems.

Although some important advances have been made in synaptic arrangement technology, technical problems still exist. In such a field, artificial synapse networks (ASNs) implemented using software have already been commercialized, but the ASNs do not have a sufficient processing speed to drive complex networks. In addition, CMOS silicon-based devices have high manufacturing costs and environmental problems. Electronic synaptic devices may be applied to intelligent semiconductor systems and brain nervous systems that are insertable into the human body. However, until now, the development of an electronic synaptic network that can be fused with the human body has not been made.

### RELATED ART DOCUMENTS

### Patent Documents

Korean Patent Publication No. 10-2012-0010037 Korean Patent Registration No. 10-1443271 Korean Patent Registration No. 10-2009569

### SUMMARY

Accordingly, example embodiments of the present invention are provided to substantially obviate one or more problems due to limitations and disadvantages of the related art.

Example embodiments of the present invention provide an electronic synaptic device which has a simple structure, is formed of a human-friendly material, and is applicable to an intelligent system and a biological nerve.

Example embodiments of the present invention also provide a method of manufacturing an electronic synaptic device of which a manufacturing process is simple and which is economical and eco-friendly.

In some example embodiments, an electronic synaptic device, which is based on nanocomposites including a protein, includes a) a substrate, b) a lower electrode formed on the substrate, c) a protein nanoparticle layer formed on the lower electrode, and d) an upper electrode formed on the protein nanoparticle layer. In this case, it is preferable that the protein contained in the protein nanoparticle layer is albumen, and the nanoparticles contained in the protein nanoparticle layer are graphene quantum dots (GQDs).

In other example embodiments, a method of manufacturing an electronic synaptic device includes a) mixing nanoparticles into a protein to prepare a protein nanoparticle solution, b) applying the protein nanoparticle solution on a substrate, on which a lower electrode is formed, to form a protein nanoparticle thin film layer, and c) depositing an upper electrode on the protein nanoparticle thin film layer.

### BRIEF DESCRIPTION OF DRAWINGS

Example embodiments of the present invention will become more apparent by describing example embodiments of the present invention in detail with reference to the accompanying drawings, in which:

FIG. 1 is a schematic view illustrating a structure of an electronic synaptic device according to one example embodiment of the present invention;

FIG. 2 shows a process of preparing a mixed solution of albumen and graphene quantum dots (GQDs) according to one example embodiment of the present invention;

FIGS. 3A and 3B show current-voltage characteristics of an electronic synaptic device manufactured according to one example embodiment of the present invention;

FIG. 4 is a current and voltage graph expressed as a time function for establishing durability characteristics when serial constant voltage pulses are applied to an indium-tin-oxide (ITO)/chicken egg albumen (CEA):GQD/aluminum (Al) device manufactured according to one example embodiment of the present invention; and

FIGS. 5A-5C show graphs in which FIG. 5A is an I-V curve of the ITO/CEA:GQD/Al device at a negative voltage of 0 V to −3 V, wherein the accompanying graph shows values obtained by fitting I-V data through ln (I) versus V^{1/2} at a negative voltage of 0 V to −1.2 V (region I of FIG. 5A), FIG. 5B shows values obtained by fitting I-V data through ln (I) versus ln (V) at a negative voltage of −2.3 V to −3 V (region II of FIG. 5A), FIG. 5C is an I-V curve of the ITO/CEA:GQD/Al device at a positive voltage of 0 V to 3 V, wherein the accompanying graph shows values obtained by fitting I-V data through ln (I) versus V^{0.5} at a positive voltage between 0 V and 1.3 V (region I of FIG. 5C), and FIG. 5D shows values obtained by fitting I-V through ln (I) versus ln (V) at a positive voltage of 2.3 V to 3 V (region II of FIG. 5C).

### DESCRIPTION OF EXAMPLE EMBODIMENTS

Hereinafter, the present invention will be described in more detail through example embodiments and the accompanying drawings.

The present invention relates to an electronic synaptic device, and the synaptic device refers to a device in which, when a constant voltage pulse is applied, a change in current occurs. A phenomenon in which conductance is gradually increased is referred to as potentiation, and a phenomenon in which conductance is gradually decreased is referred to as depression. The electronic synaptic device is referred to as a synaptic device in the sense that the electronic device exhibits a biological phenomenon similar to a phenomenon in which a signal is generated at a synapse between neurons of a brain.

The electronic synaptic device according to the present invention includes a substrate, a lower electrode, a protein nanoparticle layer, and an upper electrode. A conductive material, such as gold, silver, copper, aluminum, or indium-tin-oxide (ITO), is stacked on the upper electrode and the lower electrode. An insulating protein nanoparticle material interface layer, which serves to store electric charges, is formed between the upper electrode and the lower electrode.

In other words, the electronic synaptic device based on nanocomposites including a protein according to the present invention includes a) a substrate, b) a lower electrode formed on the substrate, c) a protein nanoparticle layer formed on the lower electrode, and d) an upper electrode formed on the protein nanoparticle layer.

Each component used in the present invention will be described. First, the substrate, on which the lower electrode is formed, may include glass, silicone, poly(ethylene terephthalate) (PET), poly(ethylene naphthalate) (PEN), polyethersulfone (PES), polyimide (PI), polydimethylsiloxane (PDMS), or the like. As long as a material is used in a substrate of an electronic device, the material may be used without limitation. Among the materials, plastic substrate materials such as PET, PEN, PES, PI, and PDMS are suitable for use in manufacturing a flexible device due to flexible properties thereof.

In addition, in the present invention, the lower electrode formed on the substrate or the upper electrode formed on the protein nanoparticle layer may be made of at least one selected from among metals such as aluminum (Al), gold (Au), silver (Ag), copper (Cu), platinum (Pt), tungsten (W), nickel (Ni), zinc (Zn), titanium (Ti), zirconium (Zr), hafnium (Hf), cadmium (Cd), and palladium (Pd), and a metal oxide such as ITO. Among the materials, an Al electrode material is widely used in that the Al electrode material is easier to process at a lower temperature as compared with other metals. An ITO electrode material has an advantage in that the ITO electrode material is applicable to a light-emitting device so that the synaptic device is more preferably applied to a display device.

Meanwhile, the present invention includes an insulating material interface layer made of a protein and nanoparticles, which serves to store electric charges, between the upper electrode and the lower electrode. Nanoparticles included in a protein thin film may be considered to be an important component exhibiting synaptic properties in the present invention. Usable proteins include silk fibroin, enzyme, sericin, gelatin, lysozyme, and the like. Among the usable proteins, albumen, which is an egg white protein, is human-friendly and is easy to purchase, and a solution manufacturing process thereof is simple, and thus the albumen is more preferably used in a synaptic device.

Meanwhile, the nanoparticles mixed into the protein to form the interface layer may be selected from among graphene quantum dots (GQDs), a metal, a metal oxide, a metal nitride, and a polymer compound. Specifically, for example, the nanoparticles may be used by being selected from among GQDs, CdSe/CdS quantum dots, CdSe/ZnSe quantum dots, and InP/ZnS quantum dots, or being selected from among a metal, such as Au, Ag, Cu, Pt, Ni, Al, ZnO, and Zn—Al, and a metal oxide or a metal mixture containing the metal.

In this case, preferably, the selected nanoparticles have a nanoparticle diameter ranging from 5 nm to 100 nm. This is because a thin film of an active layer has a thickness of one to several hundreds of nanometers. When a particle size is greater than the thickness of the active layer, a surface of the thin film is not uniform, and thus, properties of the synaptic device do not appear.

In addition, in the present invention, it is appropriate that the number of array layers of the protein nanoparticle layer is in the range of one to three, but the present invention is not particularly limited thereto. The number of the array layers may be appropriately adjusted according to the use. The number of the array layers is different according to processes. Three structures are common through a vacuum thermal evaporation method, a sputtering evaporation method, or a process of physical vapor deposition (PVD), chemical vapor deposition (CVD), or atomic layer deposition (ALD). However, through a solution process including spin coating, one to three array layers may be formed by mixing solutions. When the materials are prepared as described above, an electronic synaptic device is manufactured according to the following procedure. A method of manufacturing an electronic synaptic device according to the present invention includes a) mixing nanoparticles into a protein to prepare a protein nanoparticle solution, b) applying the protein nanoparticle solution on a substrate, on which a lower electrode is formed, to form a protein nanoparticle thin film layer, and c) depositing an upper electrode on the protein nanoparticle thin film layer.

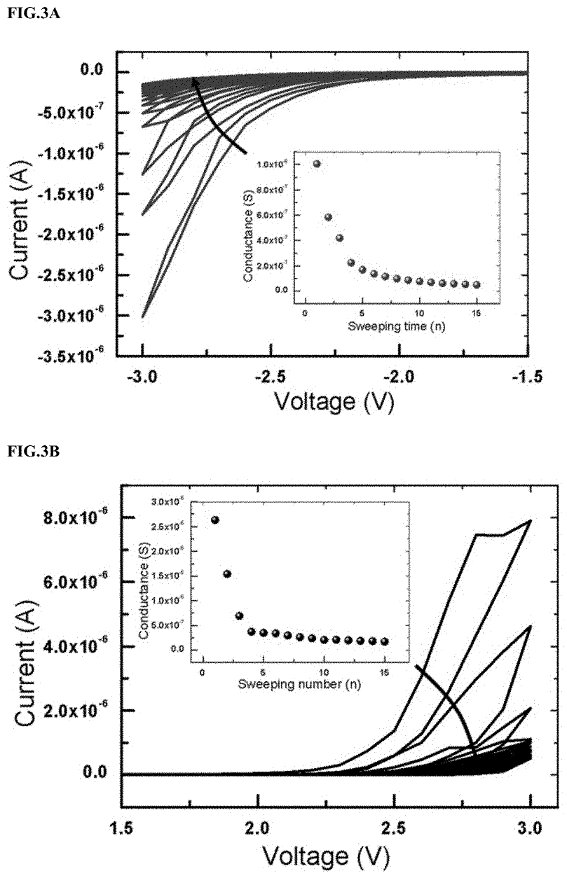

FIG. 2 illustrates an example process of mixing the nanoparticles into the protein to prepare the protein nanoparticle solution. The substrate on which the lower electrode is formed is provided, cleaned, and then coated with the protein nanoparticle solution to form the thin film. A thin film forming method applicable to the present invention may include a spin coating method, a spray coating method, a bar coating method, and the like, but the present invention is not particularly limited thereto. An appropriate coating method may be adopted and performed as necessary. Among the coating methods, the spin coating method is preferable for use in applying a mixed solution of albumen and GQDs due to advantages in that a process thereof is simple and fast and a surface of a thin film is evenly deposited. After the protein nanoparticle layer is formed, the upper electrode is deposited to complete a synaptic device. The upper electrode may also be formed using a typically used deposition method such as a vacuum thermal evaporation method, a sputtering evaporation method, a PVD method, a CVD method, or an ALD method.

The present invention will be described in more detail through the following Examples. However, it should be understood that the following Examples are provided for illustrative purposes only and the scope of the present invention is not limited to the Examples.

<Example> Manufacturing of Electronic Synaptic Device

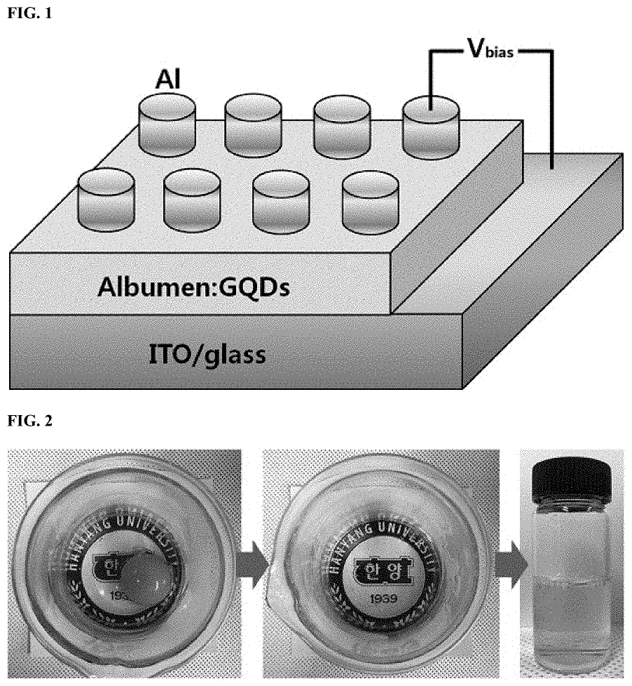

In the present Example, GQDs were used as nanoparticles, an egg white, i.e., albumen, was used as a protein, an upper electrode was made of aluminum, and a lower electrode was made of ITO. A structure of an electronic synaptic device according to the present Example is shown in FIG. 1.

As shown in images of FIG. 2, a provided egg (unfertilized egg) was separated into a white and a yolk, and the white was mixed with the GQDs to prepare a protein nanoparticle solution.

Next, a glass substrate coated with ITO was ultrasonicated for 30 minutes each in acetone, methanol, and distilled water in this order and chemically cleaned.

A thin film was formed on the cleaned glass substrate by performing a spin coating process at a speed of 3,000 RPM for 30 seconds using a prepared mixed solution of the albumen and the GQDs.

The upper electrode made of aluminum was deposited on the protein nanoparticle thin film to have a thickness of 200 nm through a shadow mask hole using a vacuum thermal evaporation process, thereby manufacturing the electronic synaptic device.

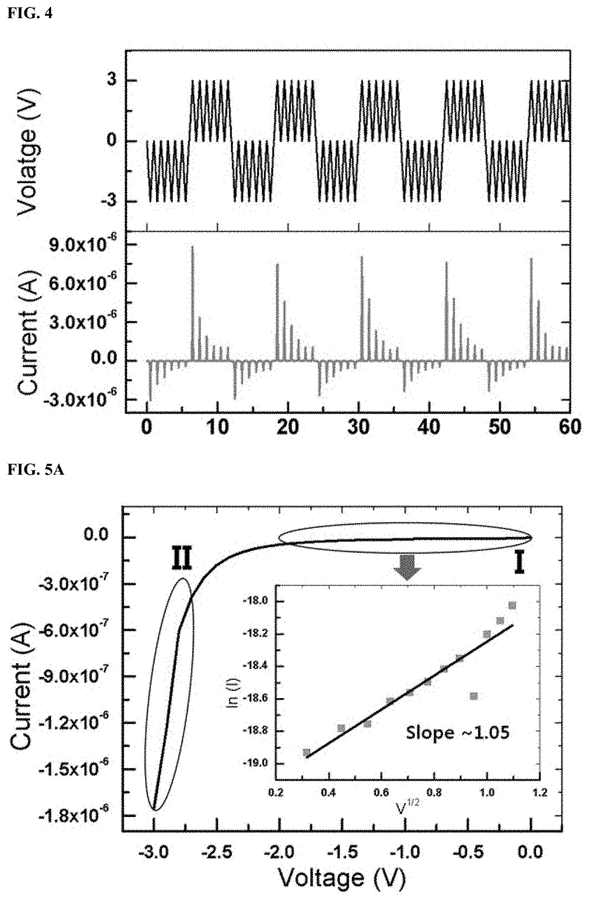

FIGS. 3A and 3B show electrical characteristics of the electronic synaptic device having an ITO/albumen:GQD/Al structure manufactured according to the present Example. Unlike current-voltage characteristics of a conventional two-terminal memory device, the electronic synaptic device shows characteristics in which, when a constant voltage is repeatedly applied, a current is continuously increased and decreased. When a negative voltage sweep of 0 V to −3 V is constantly applied 15 times, at a voltage of −3 V, a current is increased from −3.0×10⁻⁶ A to −1.48×10⁻⁷ A. On the contrary, at a positive voltage of 0 V to 3 V, a current is decreased from 7.9×10⁻⁶ A to 5.2×10⁻⁷ A. When the above results were calculated with a conductance-voltage graph, characteristics could be seen in which, when negative and positive voltage sweeps were repeated, conductance was gradually decreased. The result may be considered as a phenomenon similar to a depressive behavior in biological synapses.

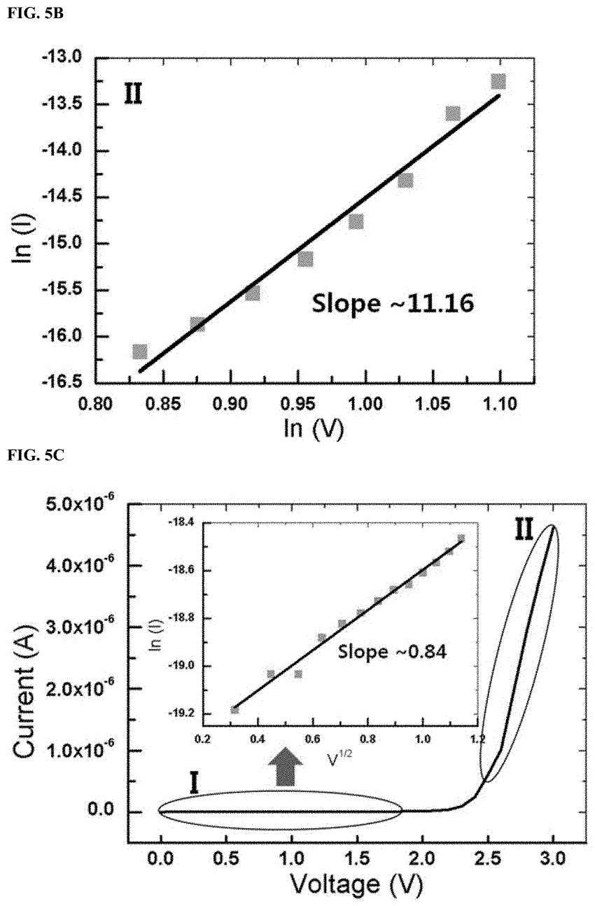

FIG. 4 is a current and voltage graph expressed as a time function for establishing durability characteristics when serial constant voltage pulses are applied to an ITO/chicken egg albumen (CEA):GQD/Al device manufactured according to the present Example. FIG. 4 is a graph showing that a current is changed when a constant voltage is applied, and it can be seen that a current is changed when constant negative and positive voltage pulses are applied. From the result, it can be confirmed once again that the electronic device manufactured according to the present invention exhibits synaptic properties. From the result, it is possible to easily manufacture a simple structure and human-friendly electronic synapse according to the present invention, and it may be expected that the electronic synapse may be used directly in an intelligent semiconductor system and a biological nerve.

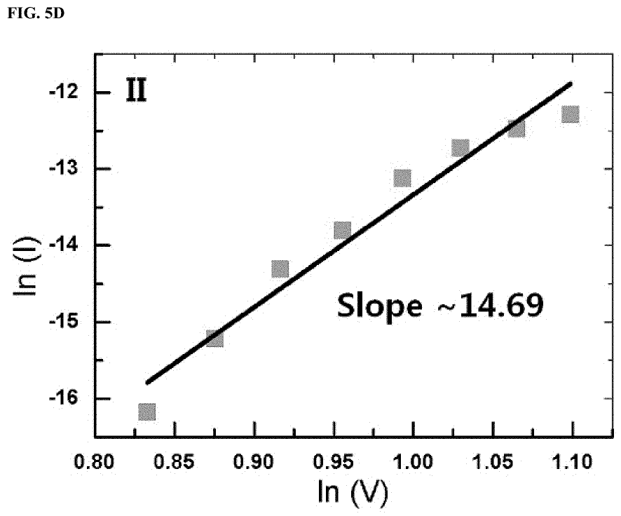

Meanwhile, current (I)-voltage (V) fitting was performed to clarify a carrier transport mechanism in the ITO/CEA:GQD/Al synaptic device manufactured according to the present Example, and results are shown in FIGS. 5A-5C. Thermionic emission (TE) and space-charge-limited-current (SCLC) models were used according to the following equations.

$$\begin{matrix}TE \text{:} I ∝ {AT}^{2} exp [ - \frac{q ϕ}{kT} + {q ( \frac{{q}^{3} V}{4 π e} )}^{1 \text{/} 2} ] , & ( 1 ) \\ SCLC \text{:} I ∝ {V}^{a} . & ( 2 )\end{matrix}$$

Here, I, V, A, T, ε, φ, k, and q refer to a current, an applied voltage, a Richardson's constant, an absolute temperature, a dielectric constant, a barrier height, a Boltzmann's constant, and electric charges, respectively.

FIG. 5A shows an I-V curve when a second sweep at a negative voltage of 0 V to −3 V is applied to an electronic synaptic device. The accompanying small graph shows a fitted graph at a negative voltage sweep. An ln (I) versus V^{1/2} curve is linear at a voltage less than −1.2 V (region I) and indicates that TE dominates carrier transmission in a corresponding region. As shown in FIG. 5B, a slope of an ln (I) versus ln (V) graph at a negative voltage of −2.3 V to −3 V (region II) is linear and is about 11.16. In the region, charge transport of the synaptic device is dominated by SCLC conduction, which is due to charge trapping by GQDs, and a gradual change in conductance is due to the introduction of the GQDs. As is well known, the GQDs exhibit an excellent charge storage function in the potential applications of electronic devices, and charge storage capacity thereof comes from charge trapping by the GQDs, which affects material transport. Electric carriers at a first negative voltage pulse are injected from an Al electrode to an albumin:GQD active layer through TE, and in this case, a current is highest. A transmission mechanism is modulated by a value of a voltage sweep time and shows several states generated from the gradual oxidation of CEA or the generation of more iron (Fe) ions. In addition, some of the injected carriers are trapped by the GQDs to form space charges. The space charges may induce an internal reverse electric field, and thus, an external electric field is weakened, and charge injection is suppressed. Thus, conductivity of an e-synapse is decreased, and the e-synapse tends to be converted from a low resistive state (LRS) to a high resistive state (HRS).

FIGS. 5C and 5D are graphs drawn through data fitted with a second sweep at a positive voltage of 0 V to 3 V. As shown at the beginning of FIG. 5C, a linear relationship is present between ln (I) and V^{1/2} at a voltage less than 1.3 V (region I) and is shown through the accompanying small graph. In FIG. 5D, linear data could be acquired by fitting ln (I) versus ln (V) at a positive voltage between 2.3 V and 3 V (region II). In a positive voltage section, it can be proved through I-V fitting results that TE and SCLC mechanisms are important in the e-synaptic device as in a negative voltage section. In addition, at a positive voltage, conductance can be restored by releasing previously trapped electric charges, but carriers injected at a next positive voltage are captured again by GQDs, resulting in a switching operation from an LRS to an HRS. Here, it should be noted that such a process is repeated when a polarity of a voltage is reversed again. As a result, the e-synapse is expected to exhibit high operational stability.

The present invention provides a method of manufacturing a two-terminal structure electronic synaptic device which has a simple structure, fast operation characteristics, low fabrication costs, and potential applications for high density integration.

An electronic synaptic device according to the present invention can be manufactured based on a human-friendly protein material that is easily accessible around us. Here, a nanocomposite thin film in which nanoparticles are mixed into a protein has a charge transport and operation process showing electronic synaptic properties. Nanocomposites including a protein can be manufactured through a simple and inexpensive process.

In addition, a human-friendly material constituting an electronic synapse presented in the present invention has high utility in that the human-friendly material is usable directly in an intelligent semiconductor system and a biological nerve.

What is claimed is:

1. An electronic synaptic device based on nanocomposites including a protein, comprising:
a) a substrate;
b) a lower electrode formed on the substrate;
c) a protein nanoparticle layer formed on the lower electrode; and
d) an upper electrode formed on the protein nanoparticle layer.

2. The electronic synaptic device of claim 1, wherein the protein contained in the protein nanoparticle layer is selected from among albumen, silk fibroin, enzyme, sericin, gelatin, and lysozyme.

3. The electronic synaptic device of claim 2, wherein the protein is albumen.

4. The electronic synaptic device of claim 1, wherein the nanoparticles contained in the protein nanoparticle layer are at least one selected from among graphene quantum dots (GQDs), CdSe/CdS quantum dots, CdSe/ZnSe quantum dots, and InP/ZnS quantum dots.

5. The electronic synaptic device of claim 1, wherein the nanoparticles contained in the protein nanoparticle layer are a metal or mixture selected from among gold (Au), silver (Ag), copper (Cu), platinum (Pt), nickel (Ni), aluminum (Al), ZnO, and Zn—Al, or a metal oxide containing the metal.

6. The electronic synaptic device of claim 1, wherein the nanoparticles contained in the protein nanoparticle layer have a diameter ranging from 5 nm to 100 nm.

7. The electronic synaptic device of claim 1, wherein the number of array layers of the protein nanoparticle layer is in a range of one to three.

8. The electronic synaptic device of claim 1, wherein the upper electrode or the lower electrode is made of at least one selected from among aluminum (Al), gold (Au), silver (Ag), copper (Cu), platinum (Pt), tungsten (W), nickel (Ni), zinc (Zn), titanium (Ti), zirconium (Zr), hafnium (Hf), cadmium (Cd), palladium (Pd), indium-tin-oxide (ITO), and a mixture thereof.

9. The electronic synaptic device of claim 1, wherein the substrate is made of at least one selected from among glass, silicone, poly(ethylene terephthalate) (PET), poly(ethylene naphthalate) (PEN), polyethersulfone (PES), polyimide (PI), and polydimethylsiloxane (PDMS).

10. A method of manufacturing an electronic synaptic device, the method comprising:
a) mixing nanoparticles into a protein to prepare a protein nanoparticle solution;
b) applying the protein nanoparticle solution on a substrate, on which a lower electrode is formed, to form a protein nanoparticle thin film layer; and
c) depositing an upper electrode on the protein nanoparticle thin film layer.

11. The method of claim 10, wherein the protein is selected from among albumen, silk fibroin, enzyme, sericin, gelatin, and lysozyme.

12. The method of claim 10, wherein the nanoparticles are at least one selected from among graphene quantum dots (GQDs), CdSe/CdS quantum dots, CdSe/ZnSe quantum dots, and InP/ZnS quantum dots.

13. The method of claim 10, wherein the nanoparticles have a diameter ranging from 5 nm to 100 nm.

14. The method of claim 10, wherein the number of array layers of the protein nanoparticle thin film layer is in a range of one to three.

15. The method of claim 10, wherein the upper electrode or the lower electrode is made of one selected from among aluminum (Al), gold (Au), silver (Ag), copper (Cu), platinum (Pt), tungsten (W), nickel (Ni), zinc (Zn), titanium (Ti), zirconium (Zr), hafnium (Hf), cadmium (Cd), palladium (Pd), indium-tin-oxide (ITO), and a mixture thereof.

16. The method of claim 10, wherein the substrate is made of at least one selected from among glass, silicone, poly(ethylene terephthalate) (PET), poly(ethylene naphthalate) (PEN), polyethersulfone (PES), polyimide (PI), and polydimethylsiloxane (PDMS).

17. The method of claim 10, wherein the protein nanoparticle thin film layer is manufactured through a method selected from among a spin coating method, a spray coating method, and a bar coating method.
